(19) United States
(12) Patent Application Publication
(10) Pub. No.: US 2005/0215029 A1
(43) Pub. Date: Sep. 29, 2005

(54) Method for fixing wafer used in manufacturing procedure

(75) Inventors: Hsin-Ya Peng, Yangmei Town (TW); Hsien-Lung Ho, Yangmei Town (TW); Shih-Feng Shao, Yangmei Town (TW)

Correspondence Address: Webb Ziesenheim Logsdon Orkin & Hanson, P.C., 700 Koppers Building, 436 Seventh Avenue, Pittsburgh, PA, 15219-1818, US

(73) Assignee: WALSIN LIHWA CORP.

(21) Appl. No.: 10/972,797

(22) Filed: Oct. 25, 2004

(30) Foreign Application Priority Data
Mar. 25, 2004 (TW) 093108197

(51) Int. Cl. H01L 21/44; H01L 21/50

(52) U.S. Cl. 438/455; 438/458; 438/118

(57) ABSTRACT

A method for fixing a wafer used in a manufacturing procedure is provided. The method includes steps of a) providing the wafer, a handling carrier, and a thermal release tape, wherein the wafer has a first and a second surfaces; b) adhering the thermal release tape between the first surface and the handling carrier for fixing the wafer on the handling carrier; c) performing the manufacturing procedure on the second surface; and d) separating the thermal release tape, the first surface and the handling carrier from one another above a specific temperature.

### FIELD OF THE INVENTION

This invention relates to a method for fixing a wafer, and more particularly to a method for fixing a wafer used in a manufacturing procedure.

### BACKGROUND OF THE INVENTION

FIG. 1 is a schematic view showing the conventional method for fixing a wafer, wherein the method is mainly achieved by the handling carrier.

Before performing a semiconductor manufacturing procedure on the upper surface 101 of the wafer 10, the adhesive layer 11 is connected to the wafer 10 for fixing the wafer 10 on the handling carrier 12, and thereby the handling carrier 12 bears the weight of the wafer 10 to facilitate the subsequent manufacturing procedure performed on the wafer 10. In general, the adhesive layer 11 is a UV tape, the wax or the photoresist.

However, there are many limitations in the subsequent manufacturing procedure when the foresaid materials are used for fixing a wafer on a handling carrier.

(1) As the adhesive layer 11 is made of the photoresist, the wafer 10 and the handling carrier 12 easily peer in the subsequent manufacturing procedure owing to the low adhesive strength of the adhesive layer 11 or owing to the variation of the adhesive layer 11, so that the yield of the manufacturing procedure is not so good.

(2) As the adhesive layer 11 is made of the wax or the resin, owing to the very strong adhesion of the adhesive layer 11, it is hard to separate the wafer 10 and the handling carrier 12 from each other and it is also hard to remove the residual adhesive layer 11 at the end of the manufacturing procedure. Therefore, the yield of the manufacturing procedure is not so good.

(3) As the adhesive layer 11 is made of the wax, the resin or the photoresist, the wafer 10 and the handling carrier can be separated from each other only by the wet manufacturing procedure.

(4) As the adhesive layer 11 is made of the wax, the resin or the photoresist, it takes about several hours to dissolve the adhesive layer 11 by the wet manufacturing procedure. It is very time-consuming.

(5) As one of the foresaid (1)-(4) situations is present, if the wafer is thin or has a weak structure, the wafer usually breaks and chemical solvent usually remains on the wafer at the end of the manufacturing procedure.

(6) As the adhesive layer 11 is a UV tape, the manufacturing procedure above 100° C. cannot be performed owing to the property limitation of the UV tape.

In order to overcome the disadvantages of the prior art described above, the present invention provides a method for fixing a wafer used in a manufacturing procedure.

### SUMMARY OF THE INVENTION

It is an aspect of the present invention to provide a thermal release tape as the adhesive layer for fixing a wafer used in the manufacturing procedure. The thermal release tape of the present invention substitutes for the convention UV tape, the wax, the resin and the photoresist so as to facilitate the subsequent manufacturing procedures performed on the wafer.

In accordance with the present invention, the method for fixing a wafer used in a manufacturing procedure includes steps of a) providing the wafer, a handling carrier and a thermal release tape, wherein the wafer has a first and a second surfaces; b) adhering the thermal release tape between the first surface and the handling carrier for fixing the wafer on the handling carrier; c) performing the manufacturing procedure on the second surface; and d) separating the thermal release tape, the first surface and the handling carrier from one another above a specific temperature.

In accordance with the present invention, the wafer is processed in the manufacturing procedure.

Preferably, the handling carrier is made of a glass.

Preferably, the handling carrier is made of a quartz.

Preferably, the handling carrier is made of a silicon wafer.

Preferably, the handling carrier is a ceramic substrate.

Preferably, the thermal release tape is double-facedly adhesive below the specific temperature.

Preferably, the specific temperature is 120° C.

Preferably, the manufacturing procedure in the step (c) is a general semiconductor manufacturing procedure except a wet etching and a procedure performed above 200° C.

It is another aspect of the present invention to provide a method for fixing a wafer used in a manufacturing procedure. The method includes steps of (a) providing the wafer, a carrier and a thermal release tape; (b) adhering the thermal release tape between the wafer and the carrier, wherein the thermal release tape has an adhesive property below a specific temperature.

Preferably, the specific temperature is 120° C.

The above aspects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic view showing the method for fixing a wafer according to the prior art, wherein the method is mainly achieved by the handling carrier.

FIGS. 2(a)-2(e) are schematic views showing the method for fixing a wafer according to the embodiment of the present invention.

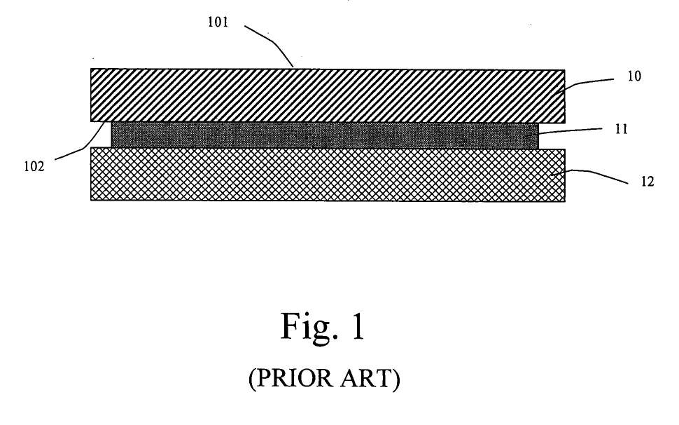

### DETAILED DESCRIPTION OF THE PREFERRED EMBODIMENT

The invention is described more specifically with reference to the following embodiments. It is to be noted that the following descriptions of preferred embodiments of this invention are presented herein for the purpose of illustration and description only; it is not intended to be exhaustive or to be limited to the precise form disclosed.

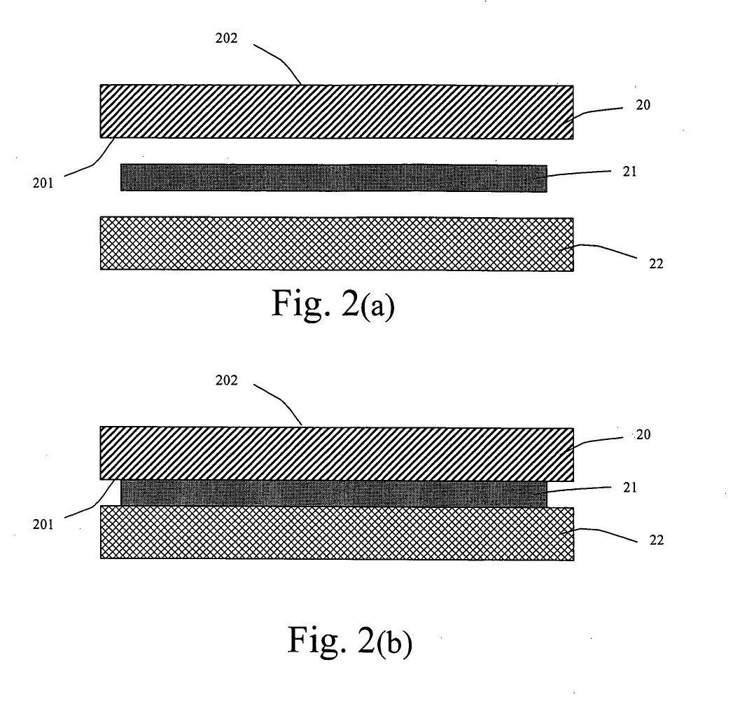

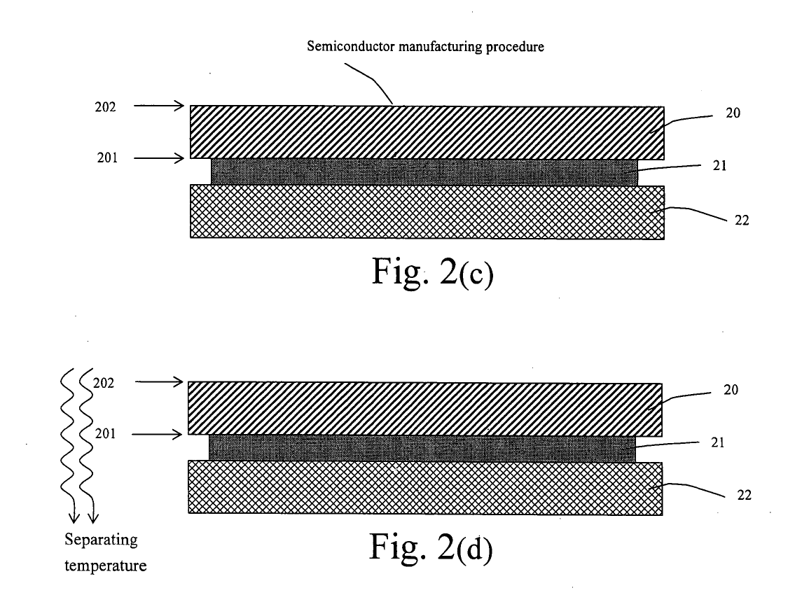

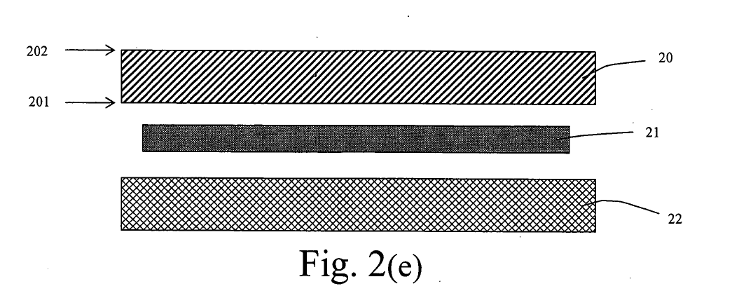

Please refer to FIGS. 2(a)-2(e) showing the method for fixing a wafer according to the embodiment of the present invention.

As shown in FIG. 2(a), the wafer 20, the thermal release tape 21 and the handling carrier 22 are provided, wherein the wafer 20 has a first surface 201 and a second surface 202.

As shown in FIG. 2(b), the thermal release tape 21 is adhered on the handling carrier 22, and the first surface 201 of the wafer 20 is adhered on the thermal release tape 21.

As shown in FIG. 2(c), the semiconductor manufacturing procedures can be performed on the second surface 202 of the wafer 20 to form the semiconductor component.

As shown in FIG. 2(d), a thermal source is provided for providing the heat above 120° C. so as to separate the handling carrier 22, the thermal release tape 21 and the wafer 20 from each another. Preferably, the thermal source can be provided at the bottom of the handling carrier 22.

As shown in FIG. 2(e), the wafer 20 and the thermal release tape 21 are taken away.

In conclusion, the method for fixing the wafer used in the manufacturing procedure in the present invention has advantages as follows.

(1) Even the wafer 20 is very thin or has a weak structure, when the wafer fixed by the method of the present invention is provided on a general machine for being processed, the risk of breaking the wafer during the manufacturing procedure and the transportation is lowered.

(2) After finishing the manufacturing procedure, if the wafer is etched and divided into wafer grains, the wafer grains and the handling carrier can be easily separated by the thermal treatment. It is not necessary to use the conventional wet procedure for separating the wafer grains and the handling carrier. Therefore, it is avoided that the wafer grains fall into the solvent at the end of the wet manufacturing procedure.

(3) When the manufacturing procedure is performed below 120° C., the adhesion strength of the thermal release tape is stronger than the conventional adhesive layer, and furthermore the thermal release tape has no quality variations, so that the fixed wafer can bear the subsequent manufacturing procedure. In addition, the wafer can have a larger area (such as a 8-inch wafer).

(4) The thermal treatment is used for separating the wafer and the handling carrier in the present invention, so as to avoid the time-consuming wet manufacturing procedure and the residuals on the surface of the wafer.

(5) The wet manufacturing procedures are performed on the wafer, which is very thin or has a weak structure, fixed by the method of the present invention, and then the breakage of the wafer during drying the wafer is avoided.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A method for fixing a wafer used in a manufacturing procedure, comprising steps of:
a) providing said wafer, a handling carrier, and a thermal release tape, wherein said wafer has a first and a second surfaces;
b) adhering said thermal release tape between said first surface and said handling carrier for fixing said wafer on said handling carrier;
c) performing said manufacturing procedure on said second surface; and
d) separating said thermal release tape, said first surface and said handling carrier from one another above a specific temperature.

2. The method according to claim 1, wherein said wafer is processed in said manufacturing procedure.

3. The method according to claim 1, wherein said handling carrier is made of a glass.

4. The method according to claim 1, said handling carrier is made of a quartz.

5. The method according to claim 1, wherein said handling carrier is made of a silicon wafer.

6. The method according to claim 1, wherein said handling carrier is a ceramic substrate.

7. The method according to claim 1, wherein said thermal release tape is double-facedly adhesive below said specific temperature.

8. The method according to claim 1, wherein said specific temperature is 120° C.

9. The method according to claim 1, wherein said manufacturing procedure in said step (c) is a general semiconductor manufacturing procedure except a wet etching and a procedure performed above 200° C.

10. A method for fixing a wafer used in a manufacturing procedure, comprising steps of:
(a) providing said wafer, a carrier and a thermal release tape;
(b) adhering said thermal release tape between said wafer and said carrier, wherein said thermal release tape has an adhesive property below a specific temperature.

11. The method according to claim 10, wherein said specific temperature is 120° C.
